(19) United States
(12) Patent Application Publication
(10) Pub. No.: US 2007/0231713 A1
(43) Pub. Date: Oct. 4, 2007

(54) Anti-reflective coating for out-of-band illumination with lithography optical systems

(76) Inventor: Robert L. Bristol, Portland, OR (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/395,878

(22) Filed: Mar. 31, 2006

(51) Int. Cl. G03F 1/00

(52) U.S. Cl. 430/5

(57) ABSTRACT

As anti-reflective coating for out-of-band illumination in a lithography system is described. An optical element with such a coating may include a surface to reflect an intended waveband of light impinging on the optical element and a coating to reduce the reflection of light outside of the intended waveband.

### FIELD

The present description relates to lithography for microelectronic and micromechanical devices and, in particular, to using an anti-reflective coating on lithography optical systems to reduce the impact of out-of-band illumination on the photoresist.

### BACKGROUND

Lithography is used in the fabrication of semiconductor devices. In lithography, a light sensitive material, called a “photoresist”, coats a wafer substrate. The photoresist may be exposed to light reflected from a mask to reproduce an image of the mask. When the wafer and mask are illuminated, the photoresist undergoes chemical reactions and is then developed to produce a replicated pattern of the mask on the wafer.

Extreme Ultraviolet (EUV) lithography is a promising future lithography technique. EUV light may be produced from a plasma at sufficient temperature to radiate in the desired wavelength, for example, in a range of approximately 11 nm to 15 nm. The plasma may be created in a vacuum chamber, typically by driving a pulsed electrical discharge through the target material or by focusing a pulsed laser beam onto the target material. The light produced by the plasma is then collected by nearby mirrors, multilayer Si/Mo mirrors are proposed, and reflected off the mask.

A problem with EUV light sources is that they generate light at many other wavelengths than the desired 13.5nm. Sources currently proposed produce a large amount of light across a range of 150 to 300 nm (called OOB or out-of-band radiation). There are also other wavelength ranges at which light is produced, but these are currently considered to be less important. Light in the 150-300 nm range will be reflected off the multilayer Si/Mo mirrors and in doing so will also expose the photoresist on the wafer. These relatively long wavelengths will not properly focus onto the features of interest, but are still sufficiently energetic to activate the photoresist, thus degrading the overall pattern fidelity.

### BRIEF DESCRIPTION OF THE DRAWINGS

Embodiments of the present invention may be understood more fully from the detailed description given below and from the accompanying drawings of various embodiments of the invention. The drawings, however, should not be taken to be limiting, but are for explanation and understanding only.

FIG. 1 is a diagram of a cross-section of an optical element for photolithography with an anti-reflective coating according to an embodiment of the invention;

FIG. 2 is a process diagram of a cross-section of an optical element for photolithography with a scatter coating according to an embodiment of the invention;

FIG. 3 is a diagram of a semiconductor fabrication device suitable for application to the present invention; and

FIG. 4 is a diagram of an optical system for lithography in a semiconductor fabrication device containing optical elements that may be coated according to an embodiment of the present invention.

### DETAILED DESCRIPTION

A top coat anti-reflective coating (ARC) may be applied to the reflective optics of a photolithography imaging system (“lithography tool”) to reduce the out-of-band (OOB) illumination reflected from the optics that therefore impinges upon the photoresist on the wafer. The ARC may be applied to the collection optics, the illumination optics, or the projection optics of the lithography tool or to any other optical surface in the light path between the lamp and the reticle. Properly designed ARCs may be able to lower the. OOB illumination reaching the wafer from 5% of the total in-band illumination to 1% with less than 25% loss of the EUV illumination.

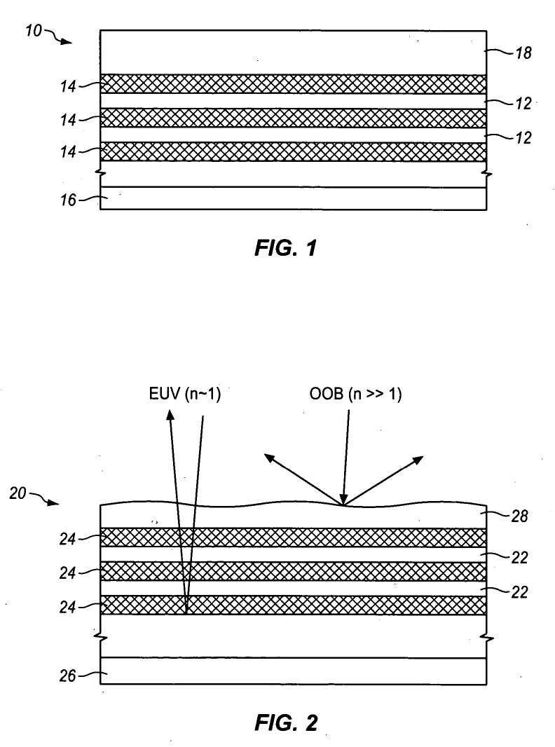

FIG. 1 is a simplified cross-sectional diagram of a reflective optical element of the type that may be used in an EUV lithography tool. The reflective optical element 10 has a sequence of alternating silicon 12 and molybdenum 14 coatings on a substrate 16. There may forty or more layers of each type. The layers establish standing waves which cause EUV illumination to be reflected. A capping layer, such as Ru, may be applied to the top of the Mo/Si stack to improve resistance to chemical degradation. While such a reflective coating will reflect most of the EUV illumination, around 13.5 nm, that shines on it, it will also reflect a similar amount of the OOB, specifically in the DUV (Deep Ultraviolet) wavelengths, around 150-350 nm. To reduce the amount of DUV light that is reflected, the reflective optical element of FIG. 1 also has a top coat 18 of SiC of a thickness designed to establish an approximate quarter-wavelength coating.

Sufficiently dense SiC may have a very high index of refraction in the DUV, approaching the value of 4. As the physical thickness of the quarter wavelength coating is proportionally reduced by the index of refraction, the SiC coating is relatively thin. Accordingly, to suppress wavelengths near 200 nm, a SiC coating of only about 12 nm may be necessary.. In addition, the SiC only has a moderate absorptivity of EUV. Thus overall the fraction of EUV absorbed is minimal.

The SiC layer may be applied by ion beam sputtering, direct-current magnetron sputtering, vapor deposition, atomic layer deposition, or in a variety of other ways. Other candidate materials possessing a high index of refraction and avoiding EUV-absorbing species include Si, Be, and alloys thereof.

Because the wavelength range of a quarter wavelength coating is limited, a single 10 nm coating will not be completely effective for all of the wavelengths of OOB light that is typically generated by, for example a Xenon gas discharge lamp. Although one coating may be effective enough depending on the application. To extend the effective range of the ARC, one optical element may be coated with an ARC for, for example, 200 nm OOB light, while another optical element may be coated with an ARC for, for example, 250 nm, yielding an overall average reflectivity of about 8% from 150-300 nm. This may correspond to one optical element having an ARC with a thickness of 8 nm and another optical element having an ARC with a thickness of 14 nm.

Each coating on the two different reflective optical elements may produce an average reflectivity for the OOB light of 8.4% with more and less reflectivity at particular wavelengths. Thus, the two ARC coatings together would reduce the effective flare contribution from OOB to about 1%. On the other hand, the transmission of the EUV light (via reflection of the optical elements) through the pair of elements assuming that the light makes a double-pass through each element is about 81%.

In another embodiment a coating may be placed on three different optical elements. In the example of EUV at 13.5 nm and OOB from 150-30 nm, a 3-layer combination of 4, 6, and 8 nm would reflect about 6.4% of the OOB and absorb about 15% of the EUV light. The three coating approach presents a small advantage in reducing the OOB at the cost of losing another 6 percentage points of the EUV. The choice of the 2-coating approach vs 3-coating approach will come down to an engineering balance between the amount of OOB which can be tolerated vs. the amount of EUV which needs to be transmitted. The best choice of thicknesses and the number of ARCs to use will depend upon the particular photolithography process, the nature of the optical equipment and even the type of photoresist that is to be used. The actual results may be improved by placing the ARC in places corresponding to where the photoresist will be the most sensitive, places where the lamp emits the most OOB, or other factors.

In addition to the layers shown in FIG. 1, an additional thin (˜2 nm) oxidation-resistant capping layer (SiO, RuO) may be placed over the SiC ARC layer. In some applications, this may not be desired because SiC is quite inert even as compared to such oxidation-resistant capping layers. As a further alternative, instead of applying an ARC to one, two, three or more optical elements, all of the coatings may be applied to a single optical element.

In another example, as shown in FIG. 2, the ARC may be made using an extra thick textured layer of Si. As shown in FIG. 2, the reflective optical element 20 has a substrate 26 upon which a multilayer Si 22 Mo 24 stack is formed. The top layer 28 is also silicon but is thicker to allow for texturing. The texturing scatters the OOB. Since the index of refraction for EUV wavelengths is nearly 1, and averages 1+3.5i from 150-300 nm, the OOB will reflect off the air-silicon interface or vacuum-silicon interface. The textured surface will cause the OOB light to scatter off the textured surface in different directions. The texture and the optical system may be designed so that the scattered light is not directed toward the reticle. This can easily be done using materials around the optical element that absorb the scattered OOB light. The EUV light, on the other hand will reflect only off the underlying multilayer.

In theory, to scatter the majority of the light would require an RMS surface roughness δ of about the wavelength of the incident light divided by 2π. So for light of 225 nm, 6 is about 35 nm. A Si layer of 50 nm, for example, should allow for surface texturing that is 35 nm deep with enough extra margin to protect the underlying multilayer coating. A 50 nm layer of silicon over the multilayer coatings after two passes will absorb roughly 15% of EUV. This may be acceptable because almost all of the OOB can be eliminated.

The texturing may be applied, for example, by a brief wet etch (hot KOH), by a dry reactive ion etch (Cl or Br), by interferometric lithography followed by an etch, by a coarse slurry polish, by mechanical force, or by a type of molding or casting. Other application processes may also be used. Alternatively, the initial silicon layer may be applied inconsistently over the surface. Sputtering, for example, may be adjusted easily to apply very rough coatings. A capping layer, such as Ru, can then be deposited on top of the textured layer to protect it from chemical contamination.

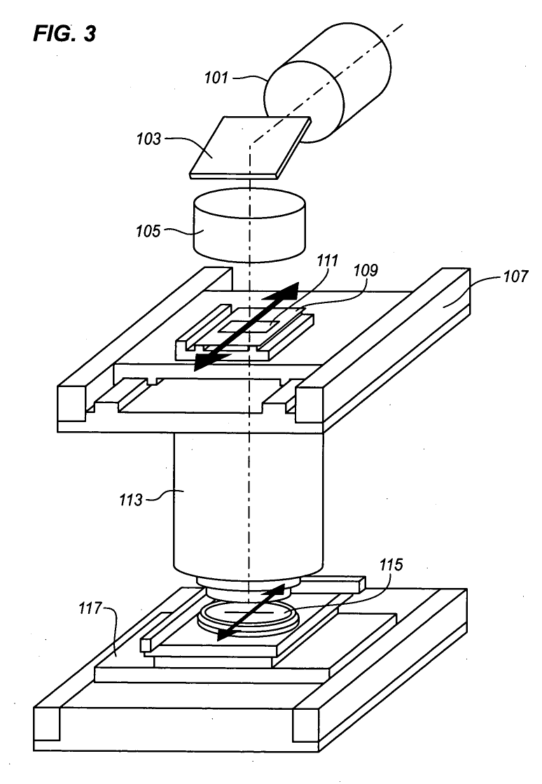

FIG. 3 shows a conventional architecture for a semiconductor fabrication machine, in this case, an optical lithography machine, that may be used to hold a mask and expose a wafer in accordance with embodiments of the present invention. The stepper may be enclosed in a sealed vacuum chamber (not shown) in which the pressure, temperature and environment may be precisely controlled. The stepper has an illumination system including a light source 101, such as a Xenon gas discharge chamber, and an optical collection system 105 to focus the light on the wafer. A reticle scanning stage 107 carries a reticle 109 which holds the mask 111. The light from the lamp is transmitted onto the mask and the light transmitted through the mask is focused further by a projection optical system with, for example, a four-fold reduction of the mask pattern onto the wafer 115.

The stepper of FIG. 3 is an example of a fabrication device that may benefit from embodiments of the present invention. Embodiments of the invention may also be applied to many other photolithography systems.

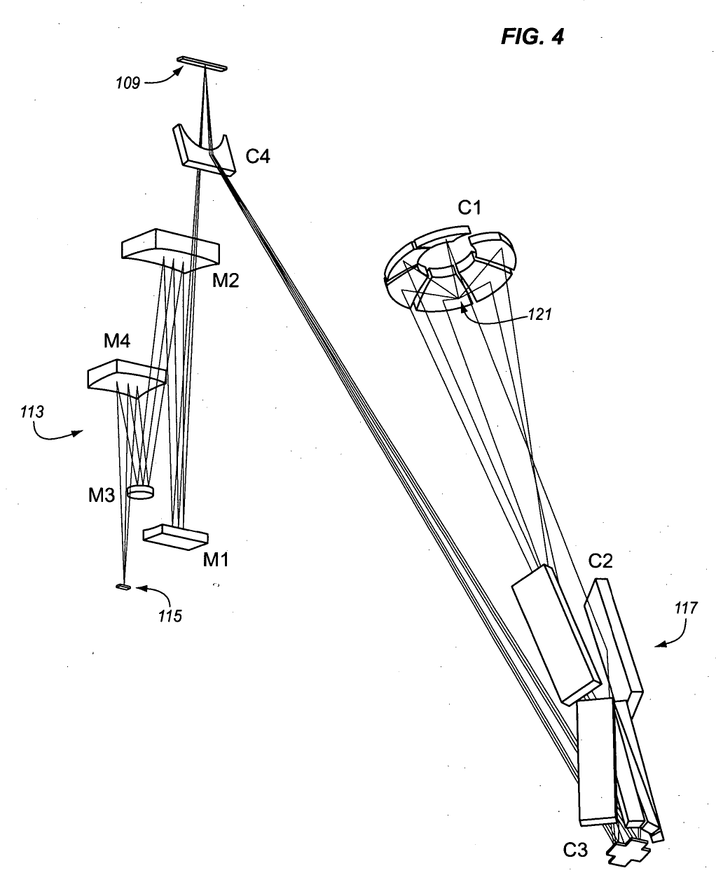

FIG. 4 is a diagram of an example of an EUV lithography system that may be used in a similar fashion as the optical lithography tool as shown in FIG. 3. The lithography tool has a plurality of mirrors, C1, C2, C3, C4 in the collection 117 to collect light from the EUV source 121. The projection optics 113 also has a set of mirrors M1, M2, M3, M4 to project the EUV illumination reflected from the mask held by the reticle 109 onto the wafer 115. The particular configuration and number of mirrors may be modified to suit different applications and improvements in designs. Each of the mirrors forms an optical element for its respective optical system.

It is to be appreciated that a lesser or more complex top layer, optical element configuration, and photolithography process or system may be used than those shown and described herein. Embodiments of the invention may be applied to reflective as well as to transmissive optical elements. Optical elements may be added to the system to impede the OOB light that have no other function in the optical system. Therefore, the configurations may vary from implementation to implementation depending upon numerous factors, such as price constraints, performance requirements, technological improvements, or other circumstances. Embodiments of the invention may also be applied to other types of photolithography systems that use different materials and devices than those shown and described herein.

In the description above, numerous specific details are set forth. However, it is understood that embodiments of the invention may be practiced without these specific details. For example, well-known equivalent materials may be substituted in place of those described herein, and similarly, well-known equivalent techniques may be substituted in place of the particular processing techniques disclosed. In other instances, well-known circuits, structures and techniques have not been shown in detail to avoid obscuring the understanding of this description.

While the embodiments of the invention have been described in terms of several examples, those skilled in the art may recognize that the invention is not limited to the embodiments described, but may be practiced with modification and alteration within the spirit and scope of the appended claims. The description is thus to be regarded as illustrative instead of limiting.

What is claimed is:

1. An optical element for a photolithography system comprising:
a surface to reflect an intended waveband of light impinging on the optical element; and
a coating to reduce the reflection of light outside of the intended waveband.

2. The optical element of claim 1, further comprising a protective layer over the coating.

3. The optical element of claim 1, wherein the coating comprises an anti-reflective coating of SiC.

4. The optical element of claim 1, wherein the coating comprises a material with an index of refraction greater than 2 in the waveband to be suppressed.

5. The optical element of claim 1, wherein the anti-reflective coating comprises a film thickness of approximately one-quarter divided by the index of refraction of light in the waveband to be suppressed.

6. The optical element of claim 5, wherein the anti-reflective coating comprises an inner transparent layer sandwiched between thin metal layers.

7. The optical element of claim 1, wherein the surface comprises a multilayer reflective coating.

8. The optical element of claim 1, wherein the coating comprises a vapor-deposited material of refractive index greater than 2 in the waveband to be suppressed.

9. The optical element of claim 8, wherein the coating comprises a direct-current magnetron sputter-deposited material.

10. The optical element of claim 9, wherein the coating comprises an ion-beam sputter-deposited material.

11. The optical element of claim 9, wherein the coating comprises an atomic layer deposition-deposited material.

12. The optical element of claim 1, wherein the coating comprises a scatter coating.

13. The optical element of claim 12, wherein the coating comprises a surface with aperiodic height variations of magnitude at least one-tenth of the wavelength to be suppressed.

14. The optical element of claim 13, wherein the scatter coating comprises a vapor deposited silicon layer with an etched surface.

15. The optical element of claim 1, further comprising a second surface to reflect an intended waveband of light and a second coating on the second surface to reduce the reflection of light outside the intended waveband,
wherein the first coating comprises an anti-reflective coating for a first wavelength of out-of-band radiation; and
the second coating comprises a second anti-reflective coating for a second wavelength of out-of-band radiation.

16. The optical element of claim 1, a second coating having a different thickness than the first coating, the second coating being chosen to reduce reflection of light of a different waveband than the first coating.

17. A lithography tool comprising:
an illumination source;
collection optics to collect the illumination source and direct it to a wafer to expose photoresist, the collection optics including an optical element, the optical element comprising a surface to reflect an intended waveband of light from the source; and
a coating to reduce the reflection of light outside of the intended waveband.

18. The lithography tool of claim 17, wherein the collection optics further comprises a second optical element, the second optical element comprising a surface to reflect the intended waveband of light impinging on the optical element; and a second coating to reduce the reflection of light outside of the intended waveband, the second coating reducing the reflection of light in a different waveband from the first coating.

19. The lithography tool of claim 17, wherein the coating comprises an anti-reflective coating of SiC.

20. A microelectronic device produced using the lithography tool of claim 17.
